(19) United States
(12) Patent Application Publication
(10) Pub. No.: US 2026/0372104 A1
(43) Pub. Date: Nov. 19, 2026

(54) SEMICONDUCTOR DEVICE

(71) Applicant: Taiwan Semiconductor Manufacturing Company, Ltd., Hsinchu (TW)

(72) Inventors: Cong-Wei Yang, Hsinchu (TW); Yu Chen Lee, Hsinchu City (TW); Chin-Hua Wang, New Taipei City (TW); Shin-Puu Jeng, Hsinchu (TW)

(73) Assignee: Taiwan Semiconductor Manufacturing Company, Ltd., Hsinchu (TW)

(21) Appl. No.: 19/754,229

(22) Filed: Jul. 26, 2026

Related U.S. Application Data
(62) Division of application No. 18/454,084, filed on Aug. 23, 2023.

(51) Int. Cl. H10W 42/00; H10W 72/20; H10W 72/29; H10W 72/90; H10W 90/00

(52) U.S. Cl. CPC H10W 42/121; H10W 72/20; H10W 72/90; H10W 90/401; H10W 72/283; H10W 72/29

(57) ABSTRACT

A semiconductor device includes a substrate and a package structure disposed on the substrate. The package structure includes an interposer and an integrated circuit. The interposer includes an interposer substrate and an auxiliary anti-stress layer disposed on the interposer substrate. The integrated circuit is disposed on the interposer substrate opposite to the auxiliary anti-stress layer and includes a semiconductor substrate, an interconnection structure, conductive pads, and conductive connectors. The interconnection structure is disposed on the semiconductor substrate. The conductive pads and the conductive connectors are disposed over the interconnection structure.

### CROSS-REFERENCE TO RELATED APPLICATION

This application is a divisional application of and claims the priority benefit of a prior application Ser. No. 18/454,084, filed on Aug. 23, 2023. The entirety of the above-mentioned patent application is hereby incorporated by reference herein and made a part of this specification.

### BACKGROUND

The semiconductor integrated circuit (IC) industry has experienced rapid growth. Over the course of this growth, functional density of the devices has generally increased by the device feature size. This scaling down process generally provides benefits by increasing production efficiency, lower costs, and/or improving performance. Such scaling down has also increased the complexities of processing and manufacturing IC. For these advances to be realized, developments in IC fabrication are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are schematic cross-sectional views illustrating a manufacturing process of an integrated circuit in accordance with some embodiments of the disclosure.

FIG. 2A to FIG. 2F are schematic top views illustrating various integrated circuits.

FIG. 3A to FIG. 3E are schematic cross-sectional views illustrating a manufacturing process of a package structure in accordance with some embodiments of the disclosure.

FIG. 4A to FIG. 4C are schematic cross-sectional views illustrating a manufacturing process of a semiconductor device in accordance with some embodiments of the disclosure.

FIG. 5 is a schematic cross-sectional view illustrating a semiconductor device in accordance with some alternative embodiments of the disclosure.

FIG. 6 is a schematic cross-sectional view illustrating a semiconductor device in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

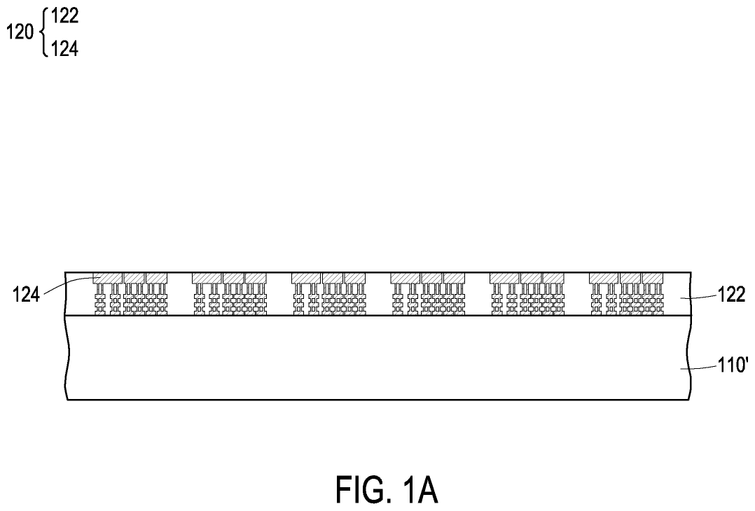

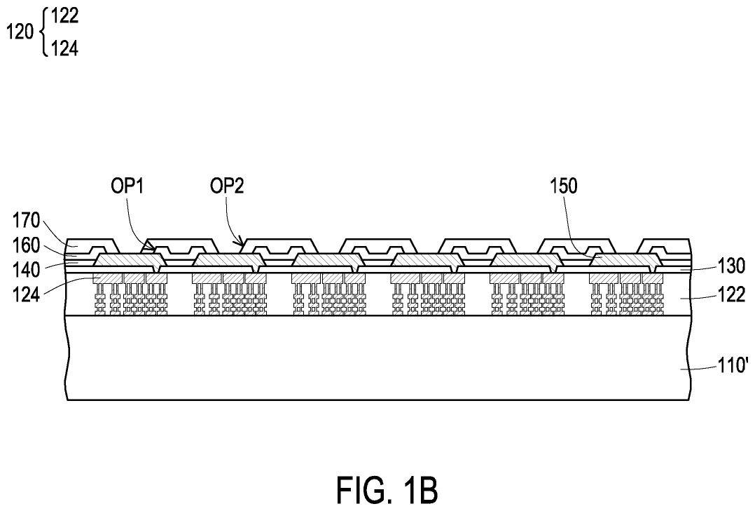

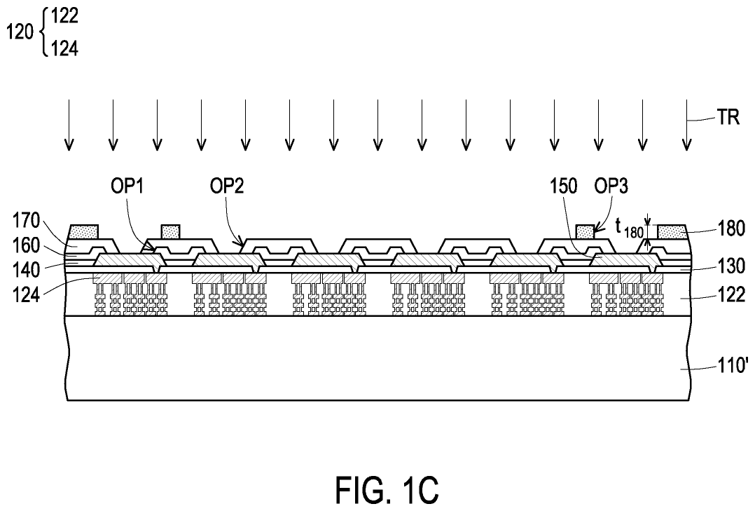

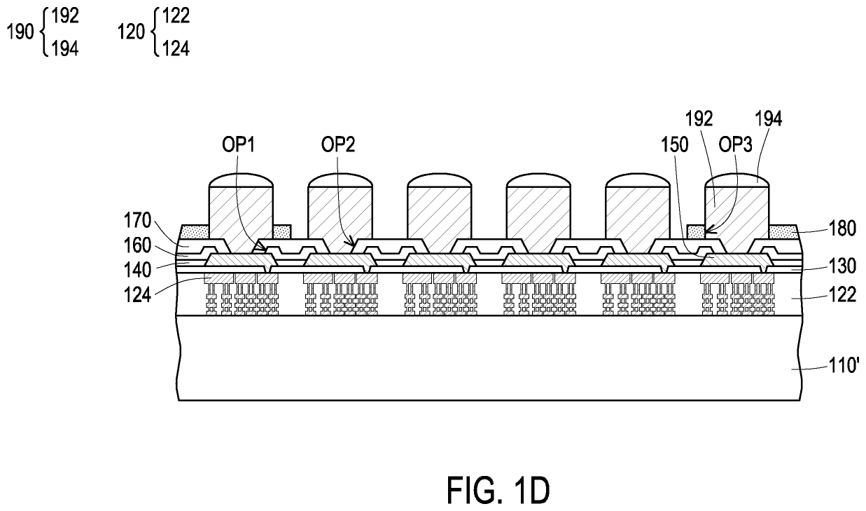

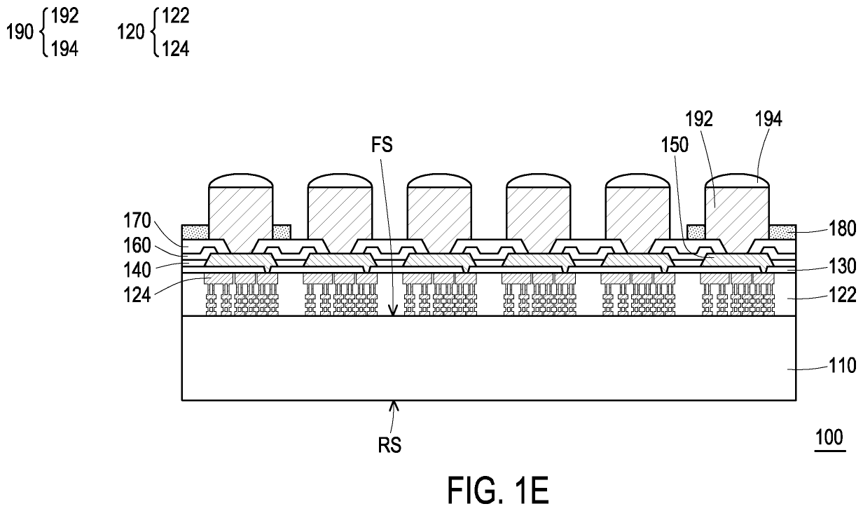

FIG. 1A to FIG. 1E are schematic cross-sectional views illustrating a manufacturing process of an integrated circuit 100 in accordance with some embodiments of the disclosure. Referring to FIG. 1A, a semiconductor wafer 110′ is provided. In some embodiments, the semiconductor wafer 110′ is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor wafer 110′ has active components (e.g., transistors or the like) and passive components (e.g., resistors, capacitors, inductors, or the like) formed therein.

In some embodiments, an interconnection structure 120 is formed on the semiconductor wafer 110′. In some embodiments, the interconnection structure 120 includes an inter-dielectric layer 122 and a plurality of patterned conductive layers 124. For simplicity, the inter-dielectric layer 122 is illustrated as a bulky layer in FIG. 1A, but it should be understood that the inter-dielectric layer 122 may be constituted by multiple dielectric layers. The patterned conductive layers 124 and the dielectric layers of the inter-dielectric layer 122 are stacked alternately. In some embodiments, two vertically adjacent patterned conductive layers 124 are electrically connected to each other through conductive vias sandwiched therebetween.

In some embodiments, a material of the inter-dielectric layer 122 includes polyimide, epoxy resin, acrylic resin, phenol resin, benzocyclobutene (BCB), polybenzoxazole (PBO), or other suitable polymer-based dielectric materials. The inter-dielectric layer 122 may be formed by suitable fabrication techniques, such as spin-on coating, chemical vapor deposition (CVD), plasma-enhanced chemical vapor deposition (PECVD), or the like. In some embodiments, a material of the patterned conductive layers 124 includes aluminum, titanium, copper, nickel, tungsten, and/or alloys thereof. The patterned conductive layers 124 may be formed by electroplating, deposition, and/or photolithography and etching. It should be noted that the number of the patterned conductive layers 124 and the dielectric layers in the inter-dielectric layer 122 shown in FIG. 1A is merely an exemplary illustration, and the disclosure is not limited. In some alternative embodiments, the number of the patterned conductive layers 124 and the dielectric layers in the inter-dielectric layer 122 may be adjusted depending on the routing requirements.

Referring to FIG. 1B, a first dielectric layer 130, a second dielectric layer 140, and a plurality of conductive pads 150 are formed over the interconnection structure 120. In some embodiments, a material of the first dielectric layer 130 includes polyimide, epoxy resin, acrylic resin, phenol resin, BCB, PBO, or any other suitable polymer-based dielectric material. The first dielectric layer 130 may be formed by suitable fabrication techniques, such as spin-on coating, CVD, PECVD, or the like. In some embodiments, a plurality of openings is formed in the first dielectric layer 130 to expose portions of the topmost patterned conductive layer 124. After the openings are formed, the conductive pads 150 is formed over the first dielectric layer 130. For example, the conductive pads 150 are formed over the semiconductor wafer 110′ and the interconnection structure 120 such that the interconnection structure 120 is located between the semiconductor wafer 110′ and the conductive pads 150. In some embodiments, the locations of the conductive pads 150 correspond to the locations of the openings of the first dielectric layer 130. For example, the conductive pads 150 extend into the openings of the first dielectric layer 130 to render electrical connection between the conductive pads 150 and portions of the interconnection structure 120 (i.e., the patterned conductive layer 124). In some embodiments, the conductive pads 150 are aluminum pads, copper pads, or other suitable metal pads. The number and the shape of the conductive pads 150 may be selected based on demand.

In some embodiments, the second dielectric layer 140 is disposed on the first dielectric layer 130. As illustrated in FIG. 1B, the second dielectric layer 140 laterally surrounds the conductive pads 150. For example, the second dielectric layer 140 is in physical contact with sidewalls of each of the conductive pads 150. However, since a thickness of each conductive pad 150 is greater than a thickness of the second dielectric layer 140, at least a portion of each sidewall of each conductive pad 150 is exposed by the second dielectric layer 140. In other words, the second dielectric layer 140 partially covers each sidewall of each of the conductive pads 150. In some embodiments, the formation of the conductive pads 150 may precede the formation of the second dielectric layer 140. However, the disclosure is not limited thereto. In some alternative embodiments, the second dielectric layer 140 may be formed on the first dielectric layer 130 before the formation of the conductive pads 150.

In some embodiments, the second dielectric layer 140 is made of extreme low-k (ELK) dielectric materials. As such, in some embodiments, the second dielectric layer 140 may be referred to as an “ELK layer.” In some embodiments, the ELK dielectric material has a dielectric constant less than about 2.5. Specific examples of the ELK dielectric material include, but are not limited to, carbon doped silicon oxide, amorphous fluorinated carbon, parylene, BCB, polytetrafluoroethylene (PTFE) (Teflon), or silicon oxycarbide polymers (SiOC). In some embodiments, the ELK dielectric material includes a porous version of an existing dielectric material, such as hydrogen silsesquioxane (HSQ), porous methyl silsesquioxane (MSQ), porous polyarylether (PAE), porous SiLK, or porous silicon oxide. In some embodiments, the second dielectric layer 140 is formed by suitable fabrication techniques, such as spin-on coating, CVD, PECVD, or the like.

After the second dielectric layer 140 and the conductive pads 150 are formed on the dielectric layer 130, a passivation layer 160 and a passivation layer 170 are sequentially formed over the second dielectric layer 140 and the conductive pads 150. In some embodiments, the passivation layer 160 has a plurality of contact openings OP1 which partially exposes the conductive pads 150. In some embodiments, the passivation layer 160 is a silicon oxide layer, a silicon nitride layer, a silicon oxy-nitride layer, or a dielectric layer formed by other suitable dielectric materials. As illustrated in FIG. 1B, the passivation layer 170 covers the passivation layer 160 and has a plurality of contact openings OP2. The conductive pads 150 are partially exposed by the contact openings OP2 of the passivation layer 170. In some embodiments, the passivation layer 170 is a polyimide layer, a PBO layer, or a dielectric layer formed by other suitable polymers. In some embodiments, the passivation layer 170 may be referred to as a “post-passivation layer.” It should be noted that the passivation layer 170 may be optional in some embodiments.

Referring to FIG. 1C, an anti-stress layer 180 is formed on the passivation layer 170. That is, the anti-stress layer 180 is formed over the first dielectric layer 130, the second dielectric layer 140, the conductive pads 150, the passivation layer 160, and the passivation layer 170. In some embodiments, the anti-stress layer 180 has a plurality of contact openings OP3 which partially exposes the conductive pads 150. For example, the conductive pads 150 are exposed through the contact openings OP2 of the passivation layer 170 and the contact openings OP3 of the anti-stress layer 180. In some embodiments, a material of the anti-stress layer 180 includes polyimide, epoxy resin, epoxy molding compound (EMC), underfill material, or other suitable polymer-based dielectric materials. In some embodiments, a coefficient of thermal expansion (CTE) of the anti-stress layer 180 is about 2.6 ppm/°C to about 50 ppm/°C, and a Young's modulus of the anti-stress layer 180 is about 1 GPa to about 100 GPa.

In some embodiments, the anti-stress layer 180 is formed by the following steps. First, an anti-stress material layer (not shown) is deposited on the passivation layer 170. In other words, the anti-stress material layer is deposited over the first dielectric layer 130, the second dielectric layer 140, the conductive pads 150, the passivation layer 160, and the passivation layer 170. Thereafter, a treating process TR is performed on the anti-stress material layer to form the anti-stress layer 180. In some embodiments, the treating process TR includes a photolithography process, an etching process, a curing process, a thinning process, or a combination thereof. For example, a photolithography process and an etching process may be performed on the anti-stress material layer to pattern the anti-stress material layer. Thereafter, a curing process may be performed to cure the anti-stress material layer. In some embodiments, the curing process is performed by irradiating the anti-stress material layer with a UV light beam. After curing the anti-stress material layer, a thinning process may be performed to reduce the overall thickness of the subsequently formed anti-stress layer 180. In some embodiments, the thinning process includes a mechanical grinding process and/or a chemical mechanical polishing (CMP) process. In some embodiments, after thinning, a thickness t₁₈₀ of the anti-stress layer 180 is greater than or equal to 0.1 μm. It should be noted that depending on the pattern design or the material of the anti-stress layer 180, any of the photolithography process, the etching process, the curing process, and the thinning process in the treating process TR may be omitted.

Referring to FIG. 1D, a plurality of conductive connectors 190 is formed on the conductive pads 150 and the passivation layer 170. In some embodiments, each conductive connector 190 extends into the corresponding contact opening OP2 of the passivation layer 170 to be in physical contact with the conductive pads 150. In other words, the conductive connectors 190 are electrically connected to the conductive pads 150. In some embodiments, each conductive connector 190 includes a conductive post 192 and a conductive terminal 194. In some embodiments, the conductive post 192 includes a seed layer portion (not shown) and a conductive portion (not shown) disposed on the seed layer portion. The seed layer portion is constituted by two sub-layers. The first sub-layer of the seed layer portion may include titanium, titanium nitride, tantalum, tantalum nitride, other suitable materials, or a combination thereof. On the other hand, the second sub-layer of the seed layer portion may include copper, copper alloys, or other suitable choice of materials. Meanwhile, the conductive portion is also constituted by two sub-layers. The first sub-layer of the conductive portion may include aluminum, titanium, copper, tungsten, and/or alloys thereof. On the other hand, the second sub-layer of the conductive portion may include nickel. In some embodiments, the conducive posts 192 are formed through a sputtering process, a physical vapor deposition (PVD) process, a plating process (i.e., an electro-plating process, an electroless-plating process, an immersion plating process, or the like), or any suitable deposition processes.

In some embodiments, the conductive terminals 194 are formed on the conductive posts 192. In some embodiments, a material of the conductive terminals 194 includes solder. The conductive terminals 194 may be formed by the following steps. First, a conductive terminal material layer (not shown) is formed on the conductive posts 192 through a plating process. The plating process is, for example, an electro-plating process, an electroless-plating process, an immersion plating process, or the like. Thereafter, a reflow process is performed on the conductive terminal material layer to transform the conductive terminal material layer into the conductive terminals 194. In some embodiments, the conductive terminal material layer is reshaped during the reflow process to form hemispherical conductive terminals 194.

In some embodiments, the material of the anti-stress layer 180 and the material of the conductive connectors 190 are selected such that an equivalent CTE of the anti-stress layer 180 is greater than an equivalent CTE of the conductive connectors 190, and a Young's modulus of the anti-stress layer 180 is smaller than a Young's modulus of the conductive connectors 190.

As illustrated in FIG. 1D, some of the conductive connectors 190 are located in the contact openings OP3 of the anti-stress layer 180 while the rest of the conductive connectors 190 are not located in the contact openings OP3 of the anti-stress layer 180. That is, the anti-stress layer 180 laterally surrounds some of the conductive connectors 190. For example, as illustrated in FIG. 1D, the anti-stress layer 180 is in physical contact with sidewalls of some of the conductive connectors 190.

Referring to FIG. 1D and FIG. 1E, the structure illustrated in FIG. 1D is singulated to render a plurality of integrated circuits 100 shown in FIG. 1E. For example, the anti-stress layer 180, the passivation layer 170, the passivation layer 160, the second dielectric layer 140, the first dielectric layer 130, the interconnection structure 120, and the semiconductor wafer 110′ are singulated to form the integrated circuits 100. In some embodiments, the singulation process typically involves dicing with a rotation blade and/or a laser beam. In other words, the singulation process includes a laser cutting process, a mechanical cutting process, a laser grooving process, other suitable processes, or a combination thereof. For example, a laser grooving process may be performed on the structure illustrated in FIG. 1D to form trenches (not shown) in the said structure. Thereafter, a mechanical cutting process may be performed on the locations of the trenches to cut through the said structure, so as to divide the semiconductor wafer 110′ into semiconductor substrates 110 and to obtain the integrated circuits 100.

As illustrated in FIG. 1E, the integrated circuit 100 includes the semiconductor substrate 110, the interconnection structure 120, the first dielectric layer 130, the second dielectric layer 140, the conductive pads 150, the passivation layer 160, the passivation layer 170, the anti-stress layer 180, and the conductive connectors 190. In some embodiments, the semiconductor substrate 110 has a front surface FS and a rear surface RS opposite to the front surface FS. The interconnection structure 120 is disposed on the front surface FS of the semiconductor substrate 110. The first dielectric layer 130, the second dielectric layer 140, the conductive pads 150, the passivation layer 160, and the passivation layer 170 are sequentially disposed over the interconnection structure 120. The conductive connectors 190 are disposed on the passivation layer 170 and are electrically connected to the conductive pads 150. The anti-stress layer 180 is disposed on the passivation layer 170 to laterally surround some of the conductive connectors 190.

In some embodiments, the integrated circuit 100 is capable of performing logic functions. For example, the integrated circuit 100 may be a Central Process Unit (CPU) die, a Graphic Process Unit (GPU) die, a Field-Programmable Gate Array (FPGA), or the like.

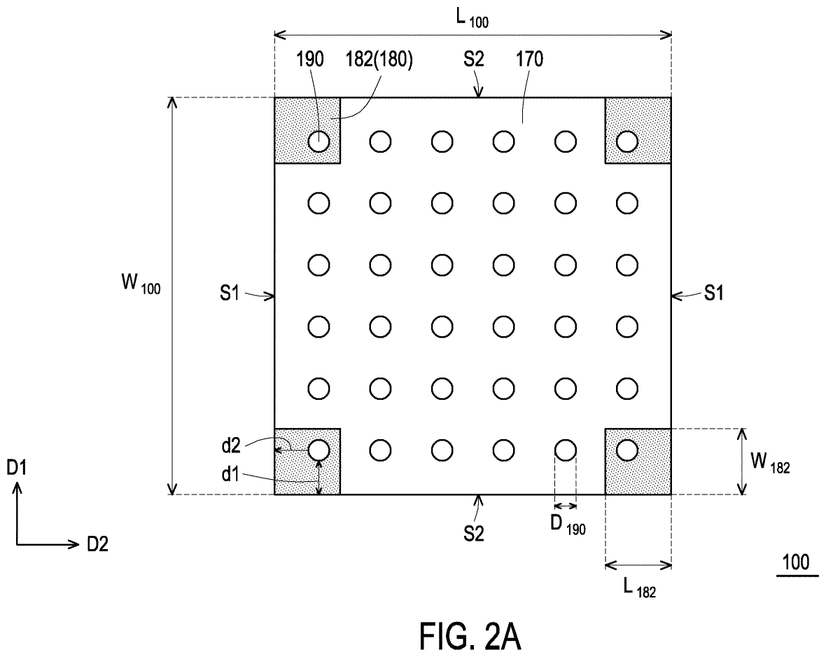

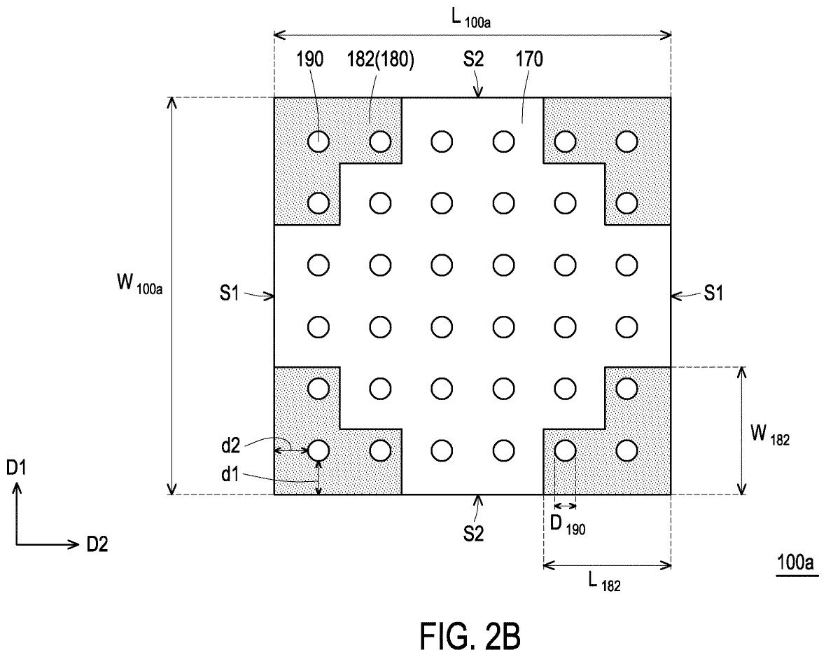

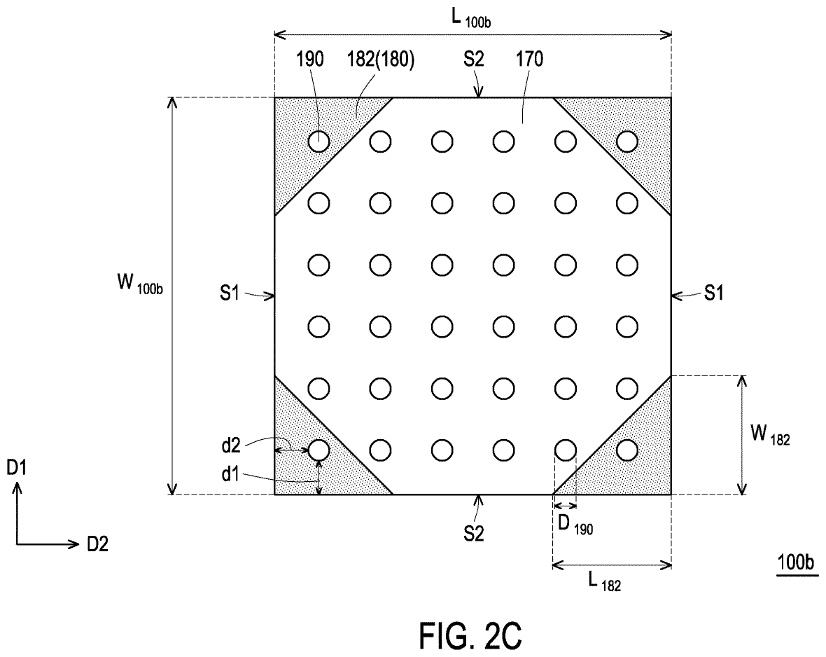

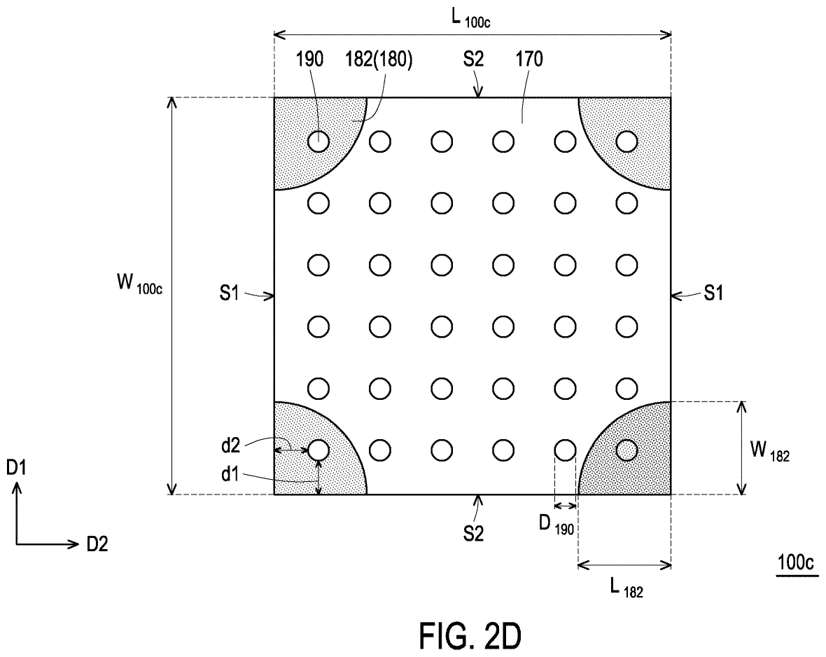

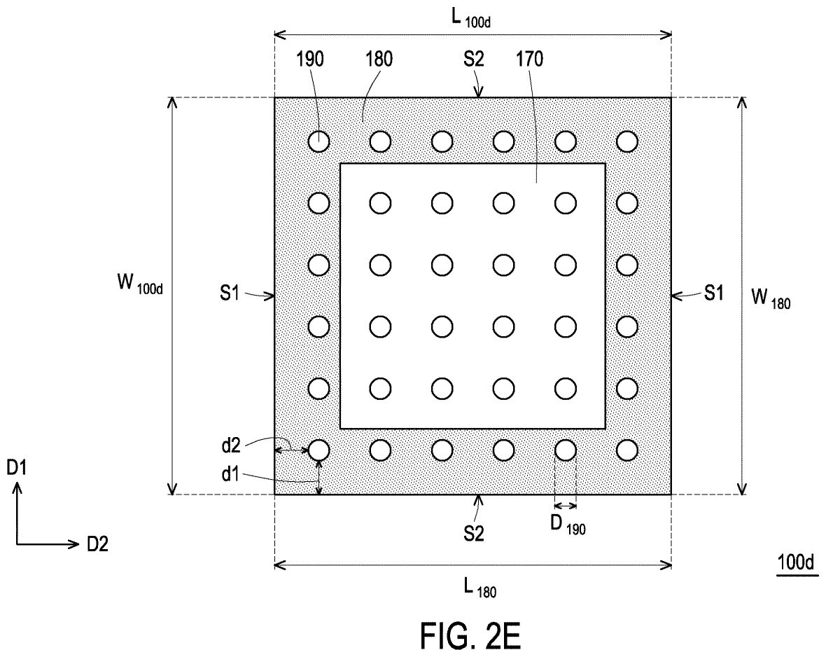

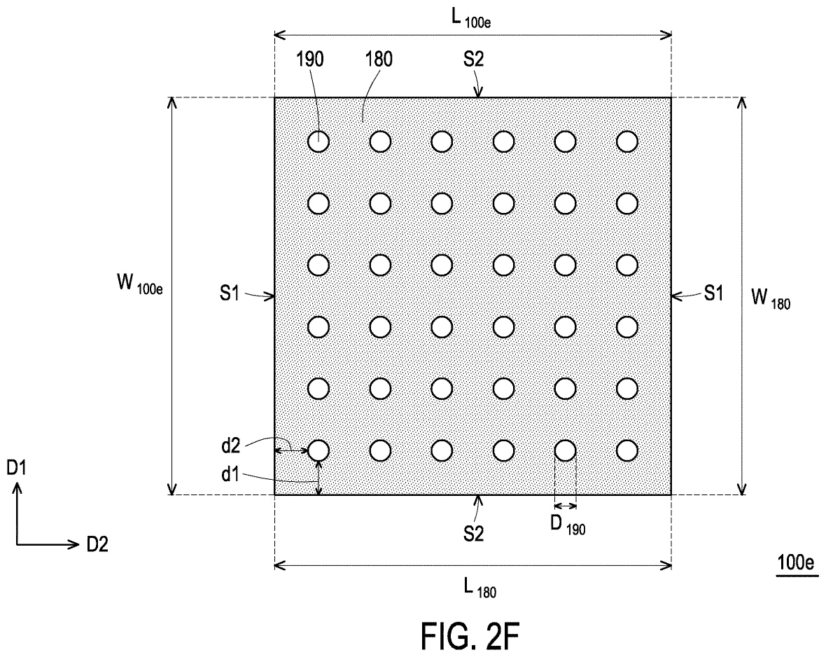

In some embodiments, the integrated circuit 100 may be utilized in a package structure. For example, the integrated circuit 100 may be assembled with other components to form a package structure. However, assembling the integrated circuit 100 with other components usually involves high temperature thermal processes (such as reflow process or the like). During the high temperature thermal processes, stress may be induced from CTE mismatch between elements to cause crack and delamination in the first dielectric layer 130, the second dielectric layer 140, and the conducive connectors 190. Nevertheless, as mentioned above, the material of the anti-stress layer 180 and the material of the conductive connectors 190 are selected such that an equivalent CTE of the anti-stress layer 180 is greater than an equivalent CTE of the conductive connectors 190 and a Young's modulus of the anti-stress layer 180 is smaller than a Young's modulus of the conductive connectors 190. As a result, the anti-stress layer 180 may serve as a mechanism against the stress derived from CTE mismatch, so as to resolve the crack and delamination issue. Depending on where the stress is concentrated at, the anti-stress layer 180 may be arranged in various configurations. These configurations of the anti-stress layer 180 will be discussed below in conjunction with FIG. 2A to FIG. 2F.

FIG. 2A to FIG. 2F are schematic top views illustrating various integrated circuits 100, 100a, 100b, 100c, 100d, and 100e. FIG. 2A is a top view of the integrated circuit 100 in FIG. 1E. Referring to FIG. 2A and FIG. 1E, the anti-stress layer 180 includes a plurality of anti-stress patterns 182 spatially separated from one another. In some embodiments, the anti-stress patterns 182 are located at four corners of the integrated circuit 100. For example, the anti-stress layer 180 laterally surrounds the conductive connectors 190 located near four corners of the integrated circuit 100. That is, the anti-stress layer 180 is in physical contact with sidewalls of the conductive connectors 190 located near four corners of the integrated circuit 100. In some embodiments, the anti-stress layer 180 (i.e., the anti-stress patterns 182) partially covers the passivation layer 170. In other words, at least a portion of the passivation layer 170 is exposed. As illustrated in FIG. 2A, each of the anti-stress patterns 182 exhibits a square from the top view. However, the disclosure is not limited thereto. In some alternative embodiments, each of the anti-stress patterns 182 may exhibit a rectangle from the top view.

In some embodiments, the integrated circuit 100 has a first side S1 and a second side S2 connected to the first side S1. As illustrated in FIG. 2A, the first side S1 extends along a first direction D1 and the second side S2 extends along a second direction D2. Meanwhile, the first direction D1 and the second direction D2 are perpendicular to each other. In some embodiments, a diameter D₁₉₀ of each of the conductive connectors 190 is d, a minimum distance between the conductive connectors 190 and the second side S2 is d1, a width W₁₀₀ of the integrated circuit 100 along the first direction D1 is W1, a width W₁₈₂ of each anti-stress pattern 182 along the first direction D1 is W2, and d1+d≤W2≤W1. Moreover, a minimum distance between the conductive connectors 190 and the first side S1 is d2, a length L₁₀₀ of the integrated circuit 100 along the second direction D2 is L1, a length L₁₈₂ of each anti-stress pattern 182 along the second direction D2 is L2, and d2+d≤L2≤L1.

In some embodiments, since the stress derived from CTE mismatch is most severe at four corners of the integrated circuit 100, by disposing the anti-stress layer 180 at four corners of the integrated circuit 100, the crack and delamination issue may be sufficiently resolved.

FIG. 2B is a top view of the integrated circuit 100a in accordance with some alternative embodiments of the disclosure. Referring to FIG. 2B, the anti-stress layer 180 includes a plurality of anti-stress patterns 182 spatially separated from one another. In some embodiments, the anti-stress patterns 182 are located at four corners of the integrated circuit 100a. For example, the anti-stress layer 180 laterally surrounds the conductive connectors 190 located near four corners of the integrated circuit 100a. That is, the anti-stress layer 180 is in physical contact with sidewalls of the conductive connectors 190 located near four corners of the integrated circuit 100a. In some embodiments, the anti-stress layer 180 (i.e., the anti-stress patterns 182) partially covers the passivation layer 170. In other words, at least a portion of the passivation layer 170 is exposed. As illustrated in FIG. 2B, each of the anti-stress patterns 182 exhibits an L shape from the top view.

In some embodiments, the integrated circuit 100a has a first side S1 and a second side S2 connected to the first side S1. As illustrated in FIG. 2B, the first side S1 extends along a first direction D1 and the second side S2 extends along a second direction D2. Meanwhile, the first direction D1 and the second direction D2 are perpendicular to each other. In some embodiments, a diameter D₁₉₀ of each of the conductive connectors 190 is d, a minimum distance between the conductive connectors 190 and the second side S2 is d1, a width W₁₀₀ₐ of the integrated circuit 100a along the first direction D1 is W1, a width W₁₈₂ of each anti-stress pattern 182 along the first direction D1 is W2, and d1+d≤W2≤W1. Moreover, a minimum distance between the conductive connectors 190 and the first side S1 is d2, a length L₁₀₀ₐ of the integrated circuit 100a along the second direction D2 is L1, a length L₁₈₂ of each anti-stress pattern 182 along the second direction D2 is L2, and d2+d≤L2≤L1.

In some embodiments, since the stress derived from CTE mismatch is most severe at four corners of the integrated circuit 100a, by disposing the anti-stress layer 180 at four corners of the integrated circuit 100a, the crack and delamination issue may be sufficiently resolved.

FIG. 2C is a top view of the integrated circuit 100b in accordance with some alternative embodiments of the disclosure. Referring to FIG. 2C, the anti-stress layer 180 includes a plurality of anti-stress patterns 182 spatially separated from one another. In some embodiments, the anti-stress patterns 182 are located at four corners of the integrated circuit 100b. For example, the anti-stress layer 180 laterally surrounds the conductive connectors 190 located near four corners of the integrated circuit 100b. That is, the anti-stress layer 180 is in physical contact with sidewalls of the conductive connectors 190 located near four corners of the integrated circuit 100b. In some embodiments, the anti-stress layer 180 (i.e., the anti-stress patterns 182) partially covers the passivation layer 170. In other words, at least a portion of the passivation layer 170 is exposed. As illustrated in FIG. 2C, each of the anti-stress patterns 182 exhibits a triangle from the top view.

In some embodiments, the integrated circuit 100b has a first side S1 and a second side S2 connected to the first side S1. As illustrated in FIG. 2C, the first side S1 extends along a first direction D1 and the second side S2 extends along a second direction D2. Meanwhile, the first direction D1 and the second direction D2 are perpendicular to each other. In some embodiments, a diameter D₁₉₀ of each of the conductive connectors 190 is d, a minimum distance between the conductive connectors 190 and the second side S2 is d1, a width W_{100b} of the integrated circuit 100b along the first direction D1 is W1, a width W₁₈₂ of each anti-stress pattern 182 along the first direction D1 is W2, and d1+d≤W2≤W1. Moreover, a minimum distance between the conductive connectors 190 and the first side S1 is d2, a length L_{100b} of the integrated circuit 100b along the second direction D2 is L1, a length L₁₈₂ of each anti-stress pattern 182 along the second direction D2 is L2, and d2+d≤L2≤L1.

In some embodiments, since the stress derived from CTE mismatch is most severe at four corners of the integrated circuit 100b, by disposing the anti-stress layer 180 at four corners of the integrated circuit 100b, the crack and delamination issue may be sufficiently resolved.

FIG. 2D is a top view of the integrated circuit 100c in accordance with some alternative embodiments of the disclosure. Referring to FIG. 2D, the anti-stress layer 180 includes a plurality of anti-stress patterns 182 spatially separated from one another. In some embodiments, the anti-stress patterns 182 are located at four corners of the integrated circuit 100c. For example, the anti-stress layer 180 laterally surrounds the conductive connectors 190 located near four corners of the integrated circuit 100c. That is, the anti-stress layer 180 is in physical contact with sidewalls of the conductive connectors 190 located near four corners of the integrated circuit 100c. In some embodiments, the anti-stress layer 180 (i.e., the anti-stress patterns 182) partially covers the passivation layer 170. In other words, at least a portion of the passivation layer 170 is exposed. As illustrated in FIG. 2D, each of the anti-stress patterns 182 exhibits a quadrant from the top view.

In some embodiments, the integrated circuit 100c has a first side S1 and a second side S2 connected to the first side S1. As illustrated in FIG. 2D, the first side S1 extends along a first direction D1 and the second side S2 extends along a second direction D2. Meanwhile, the first direction D1 and the second direction D2 are perpendicular to each other. In some embodiments, a diameter D₁₉₀ of each of the conductive connectors 190 is d, a minimum distance between the conductive connectors 190 and the second side S2 is d1, a width W_{100c} of the integrated circuit 100c along the first direction D1 is W1, a width W₁₈₂ of each anti-stress pattern 182 along the first direction D1 is W2, and d1+d≤W2≤W1. Moreover, a minimum distance between the conductive connectors 190 and the first side S1 is d2, a length L_{100c} of the integrated circuit 100c along the second direction D2 is L1, a length L₁₈₂ of each anti-stress pattern 182 along the second direction D2 is L2, and d2+d≤L2≤L1.

In some embodiments, since the stress derived from CTE mismatch is most severe at four corners of the integrated circuit 100c, by disposing the anti-stress layer 180 at four corners of the integrated circuit 100c, the crack and delamination issue may be sufficiently resolved.

FIG. 2E is a top view of the integrated circuit 100d in accordance with some alternative embodiments of the disclosure. Referring to FIG. 2E, the anti-stress layer 180 is a continuous layer. In some embodiments, the anti-stress layer 180 is located at four edges and four corners of the integrated circuit 100d. For example, the anti-stress layer 180 laterally surrounds the conductive connectors 190 that are arranged along four edges of the integrated circuit 100d. That is, the anti-stress layer 180 is in physical contact with sidewalls of the conductive connectors 190 that are arranged along four edges of the integrated circuit 100d. In some embodiments, the anti-stress layer 180 partially covers the passivation layer 170. In other words, at least a portion of the passivation layer 170 is exposed. As illustrated in FIG. 2E, the anti-stress layer 180 exhibits a ring-shape from the top view.

In some embodiments, the integrated circuit 100d has a first side S1 and a second side S2 connected to the first side S1. As illustrated in FIG. 2E, the first side S1 extends along a first direction D1 and the second side S2 extends along a second direction D2. Meanwhile, the first direction D1 and the second direction D2 are perpendicular to each other. In some embodiments, a diameter D₁₉₀ of each of the conductive connectors 190 is d, a minimum distance between the conductive connectors 190 and the second side S2 is d1, a width W_{100d} of the integrated circuit 100d along the first direction D1 is W1, a width W₁₈₀ of the anti-stress layer 180 along the first direction D1 is W2, and d1+d≤W2=W1. Moreover, a minimum distance between the conductive connectors 190 and the first side S1 is d2, a length L_{100d} of the integrated circuit 100d along the second direction D2 is L1, a length L₁₈₀ of the anti-stress layer 180 along the second direction D2 is L2, and d2+d≤L2=L1.

In some embodiments, since the stress derived from CTE mismatch is most severe at four corners of the integrated circuit 100d, by disposing the anti-stress layer 180 to at least cover the four corners of the integrated circuit 100d, the crack and delamination issue may be sufficiently resolved.

FIG. 2F is a top view of the integrated circuit 100e in accordance with some alternative embodiments of the disclosure. Referring to FIG. 2F, the anti-stress layer 180 is a continuous layer. In some embodiments, the anti-stress layer 180 covers an entire span of the integrated circuit 100e. For example, the anti-stress layer 180 laterally surrounds all of the conductive connectors 190. That is, the anti-stress layer 180 is in physical contact with sidewalls of all of the conductive connectors 190. In some embodiments, the anti-stress layer 180 completely covers the passivation layer 170. In other words, the passivation layer 170 is shielded by the anti-stress layer 180 and is not exposed.

In some embodiments, the integrated circuit 100e has a first side S1 and a second side S2 connected to the first side S1. As illustrated in FIG. 2F, the first side S1 extends along a first direction D1 and the second side S2 extends along a second direction D2. Meanwhile, the first direction D1 and the second direction D2 are perpendicular to each other. In some embodiments, a diameter D₁₉₀ of each of the conductive connectors 190 is d, a minimum distance between the conductive connectors 190 and the second side S2 is d1, a width W₁₀₀ₑ of the integrated circuit 100e along the first direction D1 is W1, a width W₁₈₀ of the anti-stress layer 180 along the first direction D1 is W2, and d1+d≤W2=W1. Moreover, a minimum distance between the conductive connectors 190 and the first side S1 is d2, a length L₁₀₀ₑ of the integrated circuit 100e along the second direction D2 is L1, a length L₁₈₀ of the anti-stress layer 180 along the second direction D2 is L2, and d2+d≤L2=L1.

In some embodiments, since the stress derived from CTE mismatch is most severe at four corners of the integrated circuit 100e, by disposing the anti-stress layer 180 to at least cover the four corners of the integrated circuit 100e, the crack and delamination issue may be sufficiently resolved.

As mentioned above, the integrated circuit 100 may be assembled with other components to form a package structure. The manufacturing process of the package structure utilizing the integrated circuit 100 will be described below.

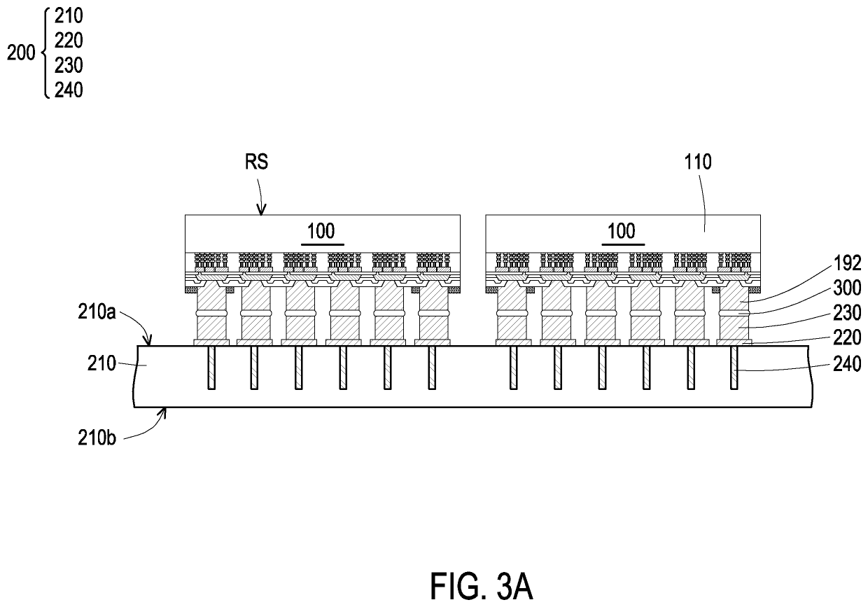

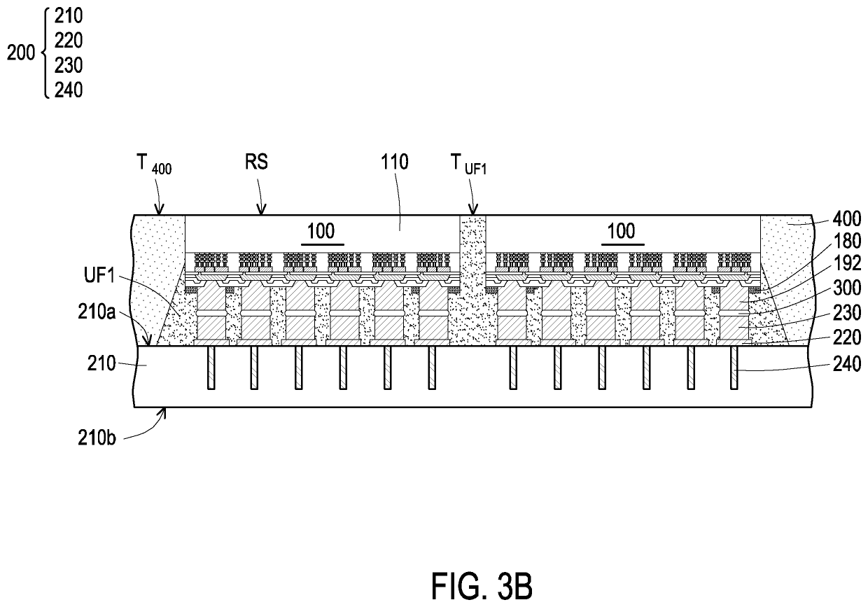

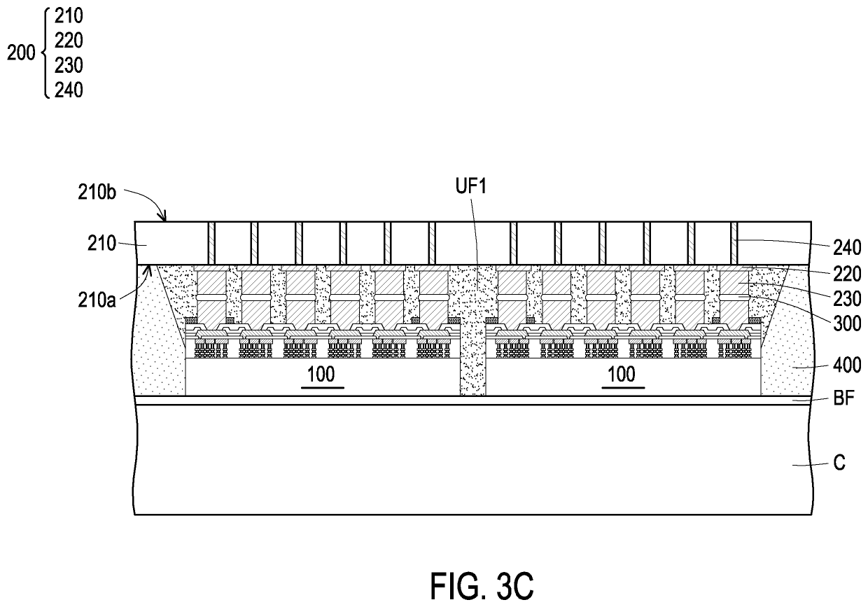

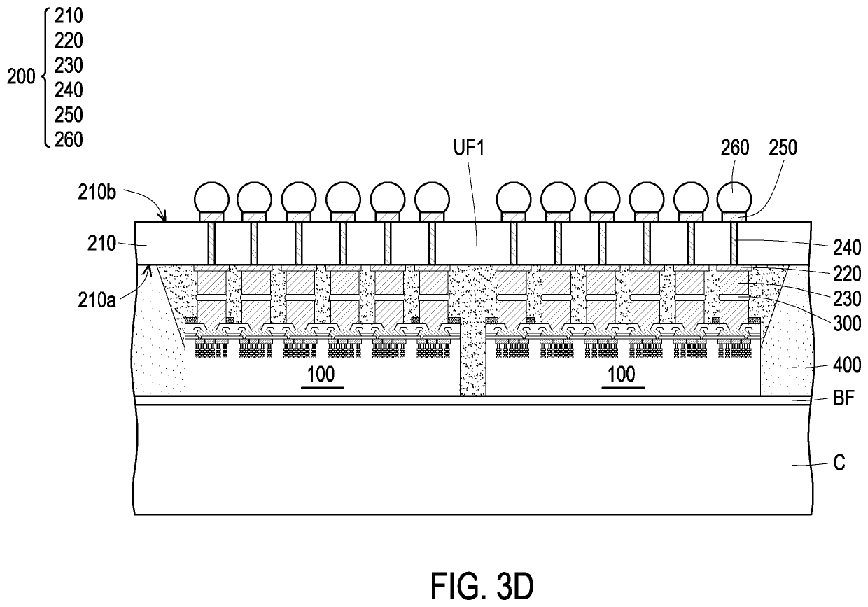

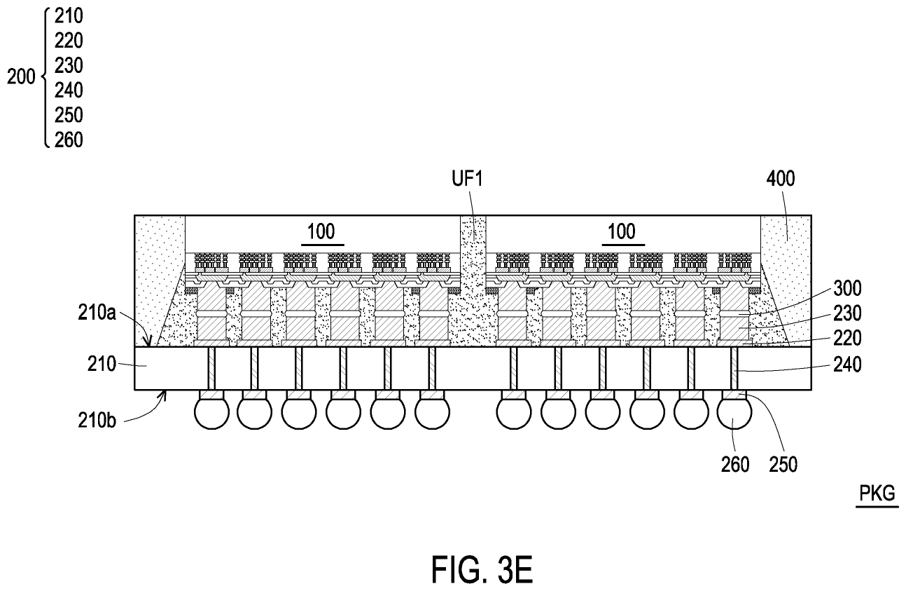

FIG. 3A to FIG. 3E are schematic cross-sectional views illustrating a manufacturing process of a package structure PKG in accordance with some embodiments of the disclosure. Referring to FIG. 3A, an interposer 200 is provided. In some embodiments, the interposer 200 includes an interposer substrate 210, a plurality of routing patterns 220, a plurality of conductive posts 230, and a plurality of through semiconductor vias (TSV) 240. In some embodiments, the interposer substrate 210 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the interposer substrate 210 includes active components (e.g., transistors or the like) and/or passive components (e.g., resistors, capacitors, inductors, or the like) formed therein. In some embodiments, the interposer substrate 210 has a first surface 210a and a second surface 210b opposite to the first surface 210a.

As illustrated in FIG. 3A, the routing patterns 220 and the conductive posts 230 are sequentially formed on the first surface 210a of the interposer substrate 210. In some embodiments, a material of the routing patterns 220 includes aluminum, titanium, copper, nickel, tungsten, or alloys thereof. The routing patterns 220 may be formed by electroplating, deposition, and/or photolithography and etching. In some embodiments, each conductive post 230 includes a seed layer portion (not shown) and a conductive portion (not shown) disposed on the seed layer portion. The seed layer portion is constituted by two sub-layers. The first sub-layer of the seed layer portion may include titanium, titanium nitride, tantalum, tantalum nitride, other suitable materials, or a combination thereof. On the other hand, the second sub-layer of the seed layer portion may include copper, copper alloys, or other suitable choice of materials. Meanwhile, the conductive portion is also constituted by two sub-layers. The first sub-layer of the conductive portion may include aluminum, titanium, copper, tungsten, and/or alloys thereof. On the other hand, the second sub-layer of the conductive portion may include nickel. In some embodiments, the conducive posts 230 are formed through a sputtering process, a PVD process, a plating process (i.e., an electro-plating process, an electroless-plating process, an immersion plating process, or the like), or any suitable deposition processes.

In some embodiments, the TSVs 240 are embedded in the interposer substrate 210. For example, one end of each TSV 240 is coplanar with the first surface 210a of the interposer substrate 210 while another end of each TSV 240 is covered by the interposer substrate 210. In some embodiments, a material of the TSVs 240 includes aluminum, titanium, copper, nickel, tungsten, or alloys thereof. In some embodiments, the TSVs 240 are in physical contact with the interposer substrate 210. However, the disclosure is not limited thereto. In some alternative embodiments, a barrier layer (not shown) is sandwiched between the TSVs 240 and the interposer substrate 210. In some embodiments, materials of the barrier layer include TiN, TaN, TiSiN, TaSiN, WSiN, TiC, TaC, TiAlC, TaAlC, TiAlN, TaAlN, or a combination thereof. In some embodiments, the barrier layer is also referred to as a “liner layer.” In some embodiments, the routing patterns 220 and the conductive posts 230 are electrically connected to the TSVs 240. For example, the routing patterns 220 are in physical contact with the TSVs 240 to render electrical connection with the TSVs 240.

As illustrated in FIG. 3A, the interposer 200 is a silicon interposer. However, the disclosure is not limited thereto. In some alternative embodiments, other types of interposers, such as redistribution layer (RDL) interposer, organic interposer, or the like, may be utilized as the interposer 200.

As illustrated in FIG. 3A, a plurality of integrated circuits 100 in FIG. 1E is bonded to the interposer 200. For example, the integrated circuits 100 are disposed over the first surface 210a of the interposer substrate 210. In some embodiments, the integrated circuits 100 are attached to the interposer 200 through connectors 300. In some embodiments, the integrated circuits 100 are bonded to the interposer 200 through the following steps. First, conductive terminals (not shown) are formed on the conductive posts 230 of the interposer 200. These conductive terminals may include solder balls or the like. Thereafter, the integrated circuits 100 are placed on the interposer 200 such that the conductive terminals 194 (shown in FIG. 1E) of the integrated circuits 100 are in physical contact with and are aligned with the conductive terminals of the interposer 200. Subsequently, a reflow process is performed to transform the conductive terminals 194 of the integrated circuits 100 and the conductive terminals of the interposer 200 together into the connectors 300, thereby bonding the integrated circuits 100 to the interposer 200. As illustrated in FIG. 3A, the connectors 300 are sandwiched between the conductive posts 192 of the integrated circuits 100 and the conductive posts 230 of the interposer 200 to render electrical connection between the integrated circuits 100 and the interposer 200.

In some embodiments, the integrated circuits 100 are attached to the interposer 200 through flip-chip bonding. In other words, the integrated circuits 100 are placed such that the rear surfaces RS of the semiconductor substrates 110 face upward. As shown in FIG. 3A, two integrated circuits 100 are bonded to the interposer 200. However, it should be noted that the number of the integrated circuits 100 shown in FIG. 3A is merely an exemplary illustration, and the disclosure is not limited. In some alternative embodiments, the number of the integrated circuits 100 may be adjusted depending on the design. For example, one single integrated circuit 100 may be bonded to the interposer 200 or more than two integrated circuits 100 may be bonded to the interposer 200. Furthermore, as shown in FIG. 3A, two identical integrated circuits 100 are bonded to the interposer 200. However, the disclosure is not limited thereto. In some alternative embodiments, integrated circuits with different functions may be bonded to the interposer 200. For example, as mentioned above, the integrated circuit 100 is capable of performing logic functions. Therefore, in some alternative embodiments, one of the integrated circuits 100 may be replaced by another integrated circuit that is capable of performing storage function. For example, one of the integrated circuits 100 may be replaced by a Dynamic Random Access Memory (DRAM), a Resistive Random Access Memory (RRAM), a Static Random Access Memory (SRAM), a Magnetoresistive Random Access Memory (MRAM), a Ferroelectric Random Access Memory (FeRAM), or the like.

Referring to FIG. 3B, an underfill layer UF1 is formed over the interposer 200 to partially encapsulate the integrated circuits 100. For example, the underfill layer UF1 wraps around the conductive posts 192 and the anti-stress layer 180 of the integrated circuits 100. The underfill layer UF1 also completely covers an inner sidewall of each integrated circuit 100 and partially covers outer sidewalls of each integrated circuit 100. For example, the portion of the underfill layer UF1 located between two adjacent integrated circuits 100 has a top surface T_{UF1} that is substantially coplanar with the rear surfaces RS of the semiconductor substrates 110 of the integrated circuits 100. However, the disclosure is not limited thereto. In some alternative embodiments, the top surface T_{UF1} of the underfill layer UF1 may be located below or above the rear surfaces RS of the semiconductor substrates 110. As illustrated in FIG. 3B, the underfill layer UF1 also wraps around the routing patterns 220 and the conductive posts 230 of the interposer 200 and the connectors 300. In some embodiments, a material of the underfill layer UF1 is an insulating material and includes a resin (e.g., epoxy resin), a filler material, a stress release agent (SRA), an adhesion promoter, other material, or a combination thereof. In some embodiments, the underfill layer UF1 is optional.

As illustrated in FIG. 3B, an encapsulant 400 is formed over the interposer 200 to encapsulate the integrated circuits 100 and the underfill layer UF1. For example, the encapsulant 400 laterally encapsulates the integrated circuits 100 and the underfill layer UF1. As illustrated in FIG. 3B, a top surface T₄₀₀ of the encapsulant 400 is substantially coplanar with the rear surfaces RS of the semiconductor substrates 110 of the integrated circuits 100 and the top surface T_{UF1} of the underfill layer UF1. That is, the encapsulant 400 exposes the semiconductor substrates 110 of the integrated circuits 100. In some embodiments, the encapsulant 400 is a molding compound, a molding underfill, a resin (such as epoxy), or the like. In some embodiments, the encapsulant 400 includes fillers. The fillers may be particles made of silica, aluminum dioxide, or the like. In some embodiments, the encapsulant 400 is formed by a molding process, an injection process, a combination thereof, or the like. The molding process includes, for example, a transfer molding process, a compression molding process, or the like.

Referring to FIG. 3B and FIG. 3C, the structure illustrated in FIG. 3B is flipped upside down and is attached to a carrier C through a bonding film BF. In some embodiments, the carrier C is made of silicon, polymer, polymer composite, metal foil, ceramic, glass, glass epoxy, tape, or other suitable material for structural support. In some embodiments, the bonding film BF may be detached from the carrier C by, e.g., shining an ultra-violet (UV) light on the carrier C in a subsequent carrier de-bonding process. For example, the bonding film BF is a light-to-heat-conversion (LTHC) coating layer or the like.

Thereafter, a planarization process is performed on the second surface 210b of the interposer substrate 210. In some embodiments, the planarization process includes a mechanical grinding process and/or a CMP process. In some embodiments, the interposer substrate 210 is grinded until the TSVs 240 are revealed. For example, after the planarization process, the TSVs 240 penetrate through the interposer substrate 210. In some embodiments, the TSVs 240 allow electrical communication between the first surface 210a and the second surface 210b of the interposer 200. In some embodiments, after the TSVs 240 are revealed, the interposer substrate 210 may be further grinded to reduce the overall thicknesses of the interposer 200. In some embodiments, after the TSVs 240 are revealed, the interposer substrate 210 is recessed such that each TSV 240 protrudes from the interposer substrate 210. Thereafter, a dielectric layer (not shown) may fill into the recess to laterally wrap around the protruded portion of each TSV 240. In some embodiments, the dielectric layer that fills into the recess includes low temperature silicon nitride or the like. However, the disclosure is not limited thereto. In some alternative embodiments, the foregoing recessing step may be omitted.

Referring to FIG. 3D, a plurality of routing patterns 250 is formed on the second surface 210b of the interposer substrate 210. In some embodiments, a material of the routing patterns 250 includes aluminum, titanium, copper, nickel, tungsten, or alloys thereof. The routing patterns 250 may be formed by electroplating, deposition, and/or photolithography and etching. In some embodiments, the routing patterns 250 are electrically connected to the TSVs 240. For example, the routing patterns 250 are in physical contact with the TSVs 240 to render electrical connection with the TSVs 240.

Thereafter, a plurality of conductive terminals 260 is formed on the routing patterns 250. In some embodiments, the conductive terminals 260 are solder balls, ball grid array (BGA) balls, or the like. In some embodiments, the conductive terminals 260 are made of a conductive material with low resistivity, such as Sn, Pb, Ag, Cu, Ni, Bi, or an alloy thereof.

In some embodiments, the routing patterns 250 and the conductive terminals 260 may be considered as part of the interposer 200. In other words, the interposer 200 includes the interposer substrate 210, the routing patters 220, the conductive posts 230, the TSVs 240, the routing patterns 250, and the conductive terminals 260.

Referring to FIG. 3D and FIG. 3E, the structure illustrated in FIG. 3D is flipped upside down. Subsequently, the carrier C and the bonding film BF are removed. In some embodiments, the carrier C and the bonding film BF are removed by a suitable process, such as etching, grinding, mechanical peeling-off, or the like. For example, the carrier C is de-bonded by exposing to a laser or UV light. The laser or UV light breaks the chemical bonds of the bonding film BF that binds to the carrier C, and the carrier C may then be de-bonded. Residues of the bonding film BF, if any, may be removed by a cleaning process performed after the carrier de-bonding process.

After the carrier C and the bonding film BF are removed, a singulation process is performed on the encapsulant 400 and the interposer 200 to obtain a plurality of package structures PKG. In some embodiments, the singulation process typically involves dicing with a rotation blade and/or a laser beam. In other words, the singulation process includes a laser cutting process, a mechanical cutting process, a laser grooving process, other suitable processes, or a combination thereof. In some embodiments, since the interposer 200 is in wafer form, the package structure PKG is considered to be formed by a chip-on-wafer process.

It should be noted that although the integrated circuit 100 is utilized in the manufacturing process of the package structure PKG in FIG. 3A to FIG. 3E, the disclosure is not limited thereto. In some alternative embodiments, the integrated circuits 100a, 100b, 100c, 100d, and 100e shown in FIG. 2A to FIG. 2E may be utilized in place of the integrated circuit 100 to form the package structure PKG.

In some embodiments, the package structure PKG may be utilized in a semiconductor device. For example, the package structure PKG may be assembled with other components to form a semiconductor device. The manufacturing process of the semiconductor device utilizing the package structure PKG will be described below.

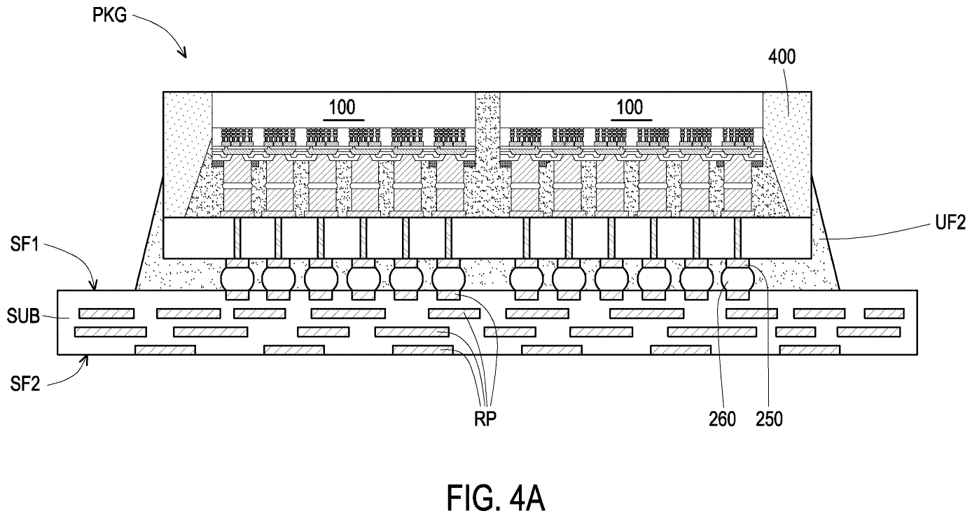

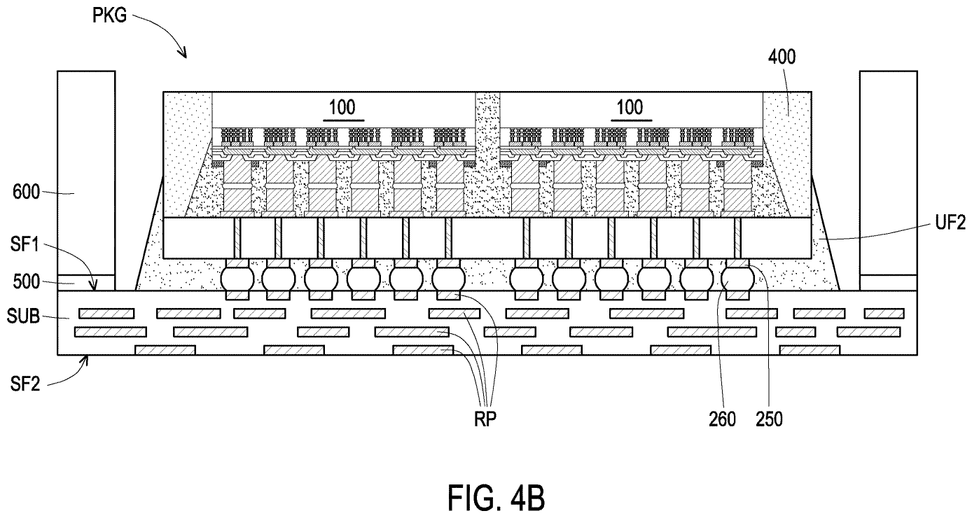

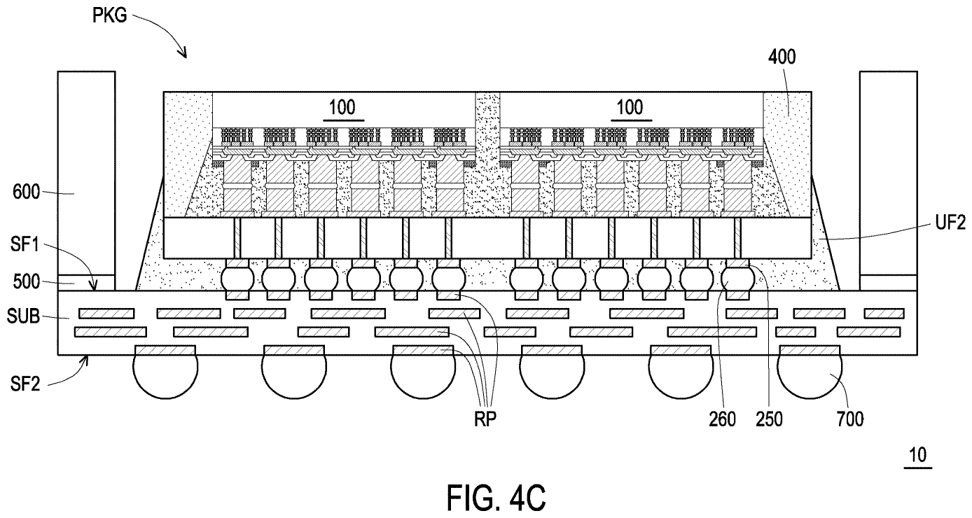

FIG. 4A to FIG. 4C are schematic cross-sectional views illustrating a manufacturing process of a semiconductor device 10 in accordance with some embodiments of the disclosure. Referring to FIG. 4A, a substate SUB is provided. In some embodiments, the substrate SUB is a printed circuit board (PCB) or the like. In some embodiments, the substrate SUB is referred to as a “circuit substrate.” In some embodiments, the substrate SUB includes a plurality of routing patterns RP embedded therein. In some embodiments, the routing patterns RP are interconnected with one another. That is, the routing patterns RP are electrically connected to one another. As illustrated in FIG. 4A, the substrate SUB has a first surface SF1 and a second surface SF2 opposite to the first surface SF1. In some embodiments, some of the routing patterns RP are exposed at the first surface SF1 and some of the routing patterns RP are exposed at the second surface SF2.

As illustrated in FIG. 4A, the package structure PKG in FIG. 3E is bonded to the first surface SF1 of the substrate SUB. In some embodiments, the package structure PKG is attached to the substrate SUB through the conductive terminals 260. For example, the conductive terminals 260 of the package structure PKG are in physical contact with the routing patterns RP exposed at the first surface SF1 of the substrate SUB to render electrical connection between the package structure PKG and the substrate SUB. In some embodiments, after the conductive terminals 260 are attached to the routing patterns RP of the substrate SUB, a reflow process may be performed to reshape the conductive terminals 260.

In some embodiments, an underfill layer UF2 is formed between the package structure PKG and the first surface SF1 of the substrate SUB. For example, the underfill layer UF2 wraps around the routing patterns 250 and the conductive terminals 260 of the package structure PKG, so as to protect the routing patterns 250 and the conductive terminals 260. In some embodiments, the underfill layer UF2 further covers portions of each sidewall of the package structure PKG. In some embodiments, a material of the underfill layer UF2 is an insulating material and includes a resin (e.g., epoxy resin), a filler material, a stress release agent (SRA), an adhesion promoter, other material, or a combination thereof. In some embodiments, the underfill layer UF2 is optional.

As shown in FIG. 4A, one package structures PKG is bonded to the substrate SUB. However, it should be noted that the number of the package structures PKG shown in FIG. 4A is merely an exemplary illustration, and the disclosure is not limited. In some alternative embodiments, the number of the package structures PKG may be adjusted depending on the design. For example, more than one package structure PKG may be bonded to the substrate SUB.

Referring to FIG. 4B, a reinforcement structure 600 is formed over the first surface SF1 of the substrate SUB. In some embodiments, the reinforcement structure 600 laterally surrounds the package structure PKG. For example, the reinforcement structure 600 encircles the package structure PKG from a top view. As illustrated in FIG. 4B, the reinforcement structure 600 is attached to the first surface SF1 of the substrate SUB through an adhesive layer 500. In some embodiment, the reinforcement structure 600 is made of metal, plastic, ceramics, or the like. The metal for the reinforcement structure 600 includes, but is not limited to, copper, stainless steel, solder, gold, nickel, molybdenum, NiFe, NiFeCr, or an alloy thereof.

Referring to FIG. 4C, a plurality of conductive terminals 700 is formed on the second surface SF2 of the substrate SUB to obtain the semiconductor device 10. In some embodiments, the conductive terminals 700 are solder balls, BGA balls, or the like. In some embodiments, the conductive terminals 700 are made of a conductive material with low resistivity, such as Sn, Pb, Ag, Cu, Ni, Bi, or an alloy thereof. In some embodiments, the conductive terminals 700 are in physical contact with the routing patterns RP exposed at the second surface SF2 of the substrate SUB.

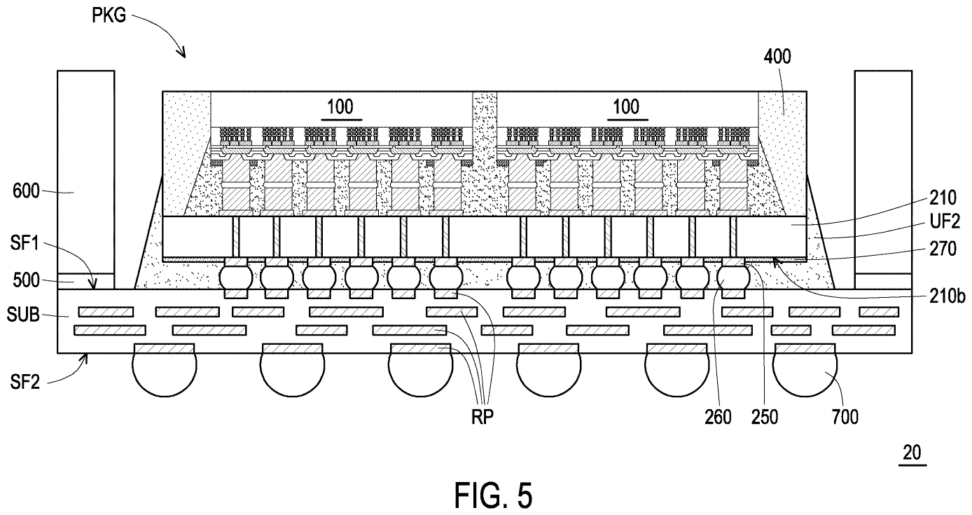

FIG. 5 is a schematic cross-sectional view illustrating a semiconductor device 20 in accordance with some alternative embodiments of the disclosure. Referring to FIG. 5, the semiconductor device 20 in FIG. 5 is similar to the semiconductor device 10 in FIG. 4C, so similar elements are denoted by the same reference numeral and the detailed descriptions thereof are omitted herein. The difference between the semiconductor device 20 in FIG. 5 and the semiconductor device 10 in FIG. 4C lies in that the interposer 200 of the semiconductor device 20 further includes an auxiliary anti-stress layer 270. In some embodiments, the auxiliary anti-stress layer 270 is formed on the second surface 210b of the interposer substrate 210. For example, the auxiliary anti-stress layer 270 laterally surrounds the routing patterns 250 of the interposer 200. In some embodiments, a material and a formation method of the auxiliary anti-stress layer 270 are similar to the anti-stress layer 180 of the integrated circuit 100, so the detailed descriptions thereof are omitted herein. Similar to the anti-stress layer 180 of the integrated circuit 100, the auxiliary anti-stress layer 270 may be formed to cover four corners of the interposer 200 or may be formed to cover an entire span of the interposer 200.

In some embodiments, the material of the auxiliary anti-stress layer 270, the material of the conductive connectors 190, and the material of the conductive terminals 260 are selected such that an equivalent CTE of the auxiliary anti-stress layer 270 is greater than an equivalent CTE of the conductive connectors 190 and the conductive terminals 260, and a Young's modulus of the auxiliary anti-stress layer 270 is smaller than a Young's modulus of the conductive connectors 190 and the conductive terminals 260. As a result, the auxiliary anti-stress layer 270 may serve as a mechanism against the stress derived from CTE mismatch, so as to resolve the crack and delamination issue of the first dielectric layer 130, the second dielectric layer 140, the conducive connectors 190, and the conductive terminals 260.

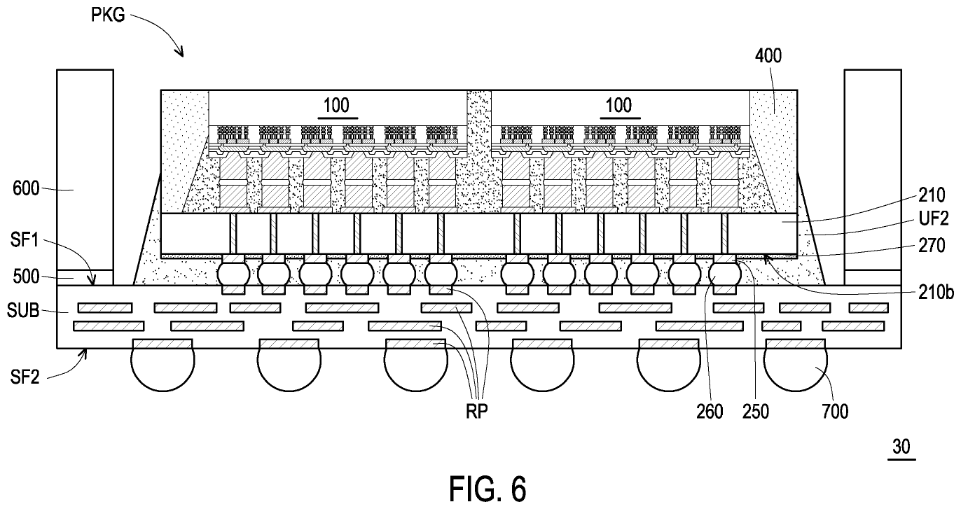

FIG. 6 is a schematic cross-sectional view illustrating a semiconductor device 30 in accordance with some alternative embodiments of the disclosure. Referring to FIG. 6, the semiconductor device 30 in FIG. 6 is similar to the semiconductor device 20 in FIG. 5, so similar elements are denoted by the same reference numeral and the detailed descriptions thereof are omitted herein. The difference between the semiconductor device 30 in FIG. 6 and the semiconductor device 20 in FIG. 5 lies in that the anti-stress layer 180 presented in the semiconductor device 20 is omitted in the semiconductor device 30.

In some embodiments, the material of the auxiliary anti-stress layer 270, the material of the conductive connectors 190, and the material of the conductive terminals 260 are selected such that an equivalent CTE of the auxiliary anti-stress layer 270 is greater than an equivalent CTE of the conductive connectors 190 and the conductive terminals 260, and a Young's modulus of the auxiliary anti-stress layer 270 is smaller than a Young's modulus of the conductive connectors 190 and the conductive terminals 260. As a result, the auxiliary anti-stress layer 270 may serve as a mechanism against the stress derived from CTE mismatch, so as to resolve the crack and delamination issue of the first dielectric layer 130, the second dielectric layer 140, the conducive connectors 190, and the conductive terminals 260.

In accordance with some embodiments of the disclosure, an integrated circuit includes a semiconductor substrate, an interconnection structure, a first dielectric layer, conductive pads, a second dielectric layer, conductive connectors, and an anti-stress layer. The interconnection structure is disposed on the semiconductor substrate. The first dielectric layer is disposed on the interconnection structure. The conductive pads are disposed on the first dielectric layer and are electrically connected to the interconnection structure. The second dielectric layer is disposed on the first dielectric layer to laterally surround the conductive pads. The conductive connectors are disposed on and electrically connected to the conductive pads. The anti-stress layer is disposed over the conductive pads and laterally surrounds some of the conductive connectors.

In accordance with some embodiments of the disclosure, a semiconductor device includes a substrate and a package structure. The package structure is disposed on the substrate and includes an interposer and an integrated circuit. The integrated circuit is disposed on the interposer and includes a semiconductor substrate, an interconnection structure, a first dielectric layer, conductive pads, a second dielectric layer, a first passivation layer, conductive connectors, and an anti-stress layer. The interconnection structure is disposed on the semiconductor substrate. The first dielectric layer is disposed on the interconnection structure. The conductive pads are disposed on the first dielectric layer. The second dielectric layer is disposed on the first dielectric layer to laterally surround the conductive pads. The first passivation layer is disposed over the second dielectric layer and the conductive pads. The conductive connectors are disposed on the first passivation layer and the conductive pads. The anti-stress layer is disposed on the first passivation layer to at least partially cover the first passivation layer.

In accordance with some alternative embodiments of the disclosure, a semiconductor device includes a substrate and a package structure. The package structure is disposed on the substrate and includes an interposer and an integrated circuit. The interposer includes an interposer substrate and an auxiliary anti-stress layer disposed on the interposer substrate. The integrated circuit is disposed on the interposer substrate opposite to the auxiliary anti-stress layer and includes a semiconductor substrate, an interconnection structure, conductive pads, and conductive connectors. The interconnection structure is disposed on the semiconductor substrate. The conductive pads and the conductive connectors are disposed over the interconnection structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a package structure disposed on the substrate, comprising:
an interposer, comprising:
an interposer substrate; and
an auxiliary anti-stress layer disposed on the interposer substrate; and
an integrated circuit disposed on the interposer substrate opposite to the auxiliary anti-stress layer, comprising:
a semiconductor substrate;
an interconnection structure disposed on the semiconductor substrate; and
conductive pads and conductive connectors disposed over the interconnection structure.

2. The semiconductor device of claim 1, wherein the integrated circuit further comprises an anti-stress layer disposed over the conductive pads, wherein the anti-stress layer laterally surrounds the conductive connectors.

3. The semiconductor device of claim 2, wherein the anti-stress layer is in physical contact with the conductive connectors.

4. The semiconductor device of claim 2, wherein the anti-stress layer comprises anti-stress patterns, and the anti-stress patterns are located at four corners of the integrated circuit.

5. The semiconductor device of claim 4, wherein each of the anti-stress patterns exhibits a square, a rectangle, a triangle, a quadrant, or an L-shape from a top view.

6. The semiconductor device of claim 2, wherein the anti-stress layer exhibits a ring-shape from a top view.

7. The semiconductor device of claim 1, wherein the interposer further comprises routing patterns disposed on the interposer substrate opposite to the integrated circuit, and the auxiliary anti-stress layer laterally surrounds the routing patterns.

8. The semiconductor device of claim 7, wherein the auxiliary anti-stress layer is in physical contact with the routing patterns.

9. The semiconductor device of claim 1, wherein the auxiliary anti-stress layer covers four corners of a surface of the interposer substrate.

10. The semiconductor device of claim 1, wherein the auxiliary anti-stress layer covers an entire bottom surface of the interposer substrate.

11. A semiconductor device, comprising:
a package structure, comprising:
an interposer, comprising:
an interposer substrate; and
an auxiliary anti-stress layer disposed on the interposer substrate; and
an integrated circuit disposed on the interposer substrate, comprising:
a semiconductor substrate;
first conductive connectors and second conductive connectors disposed over the semiconductor substrate, wherein from a top view, the second conductive connectors are closer to a center of the semiconductor substrate than the first conductive connectors are; and
an anti-stress layer over the semiconductor substate and aside the first conductive connectors, wherein the anti-stress layer encircles each of the first conductive connectors.

12. The semiconductor device of claim 11, wherein the anti-stress layer further encircles each of the second conductive connectors.

13. The semiconductor device of claim 11, wherein the anti-stress layer is in physical contact with the first conductive connectors.

14. The semiconductor device of claim 11, wherein the integrated circuit further comprises an interconnect structure and conductive pads located between the semiconductor substrate and the first conductive connectors and located between the semiconductor substrate and the second conductive connectors.

15. The semiconductor device of claim 11, wherein the first conductive connectors protrude from a top surface of the anti-stress layer.

16. The semiconductor device of claim 11, wherein the interposer further comprises routing patterns disposed on the interposer substrate, and the auxiliary anti-stress layer is in physical contact with the routing patterns.

17. A semiconductor device, comprising:
a package structure, comprising:
an interposer, comprising:
an interposer substrate; and
an auxiliary anti-stress layer disposed on the interposer substrate; and
an integrated circuit disposed on the interposer substrate, comprising:
a semiconductor substrate;
a first dielectric layer disposed over the semiconductor substrate;
conductive pads disposed on the first dielectric layer;
a second dielectric layer disposed on the first dielectric layer to laterally surround the conductive pads;
first conductive connectors and second conductive connectors disposed on the conductive pads, wherein the first conductive connectors are located at four corners of the integrated circuit; and
an anti-stress layer over the semiconductor substate and aside the first conductive connectors, wherein the anti-stress layer encircles each of the first conductive connectors.

18. The semiconductor device of claim 17, wherein the interposer further comprises routing patterns disposed on the interposer substrate, and the auxiliary anti-stress layer is in physical contact with the routing patterns.

19. The semiconductor device of claim 17, wherein the anti-stress layer further encircles each of the second conductive connectors.

20. The semiconductor device of claim 17, wherein the anti-stress layer is in physical contact with the first conductive connectors.
